(19) United States
(12) Patent Application Publication
(10) Pub. No.: US 2018/0033469 A1
(43) Pub. Date: Feb. 1, 2018

(54) MEMORY DEVICE

(71) Applicant: Hitachi, Ltd., Tokyo (JP)

(72) Inventors: Naoki MORITOKI, Tokyo (JP); Satoru HANZAWA, Tokyo (JP)

(21) Appl. No.: 15/552,813

(22) PCT Filed: May 20, 2015
(86) PCT No.: PCT/JP2015/064409

§ 371 Date: Aug. 23, 2017

(51) Int. Cl. G11C 7/10; G01R 33/09; G11C 29/12; G11C 11/02

(52) U.S. Cl. CPC G11C 7/1051; G11C 11/02; G01R 33/091; G11C 7/1096; G11C 29/12; G11C 2029/1208

(57) ABSTRACT

A memory device according to an embodiment of the present invention includes: a memory chip using a magnetic memory; and a memory controller that controls read/write to the memory chip. When the memory controller receives a read request from outside the memory controller, the memory controller transmits a read command to the memory chip to read data in the memory chip. The memory controller also transmits an update command to each area of the memory chip to write back the data stored in the memory chip.

### TECHNICAL FIELD

The present invention relates to a memory device.

### BACKGROUND ART

A memory (hereinafter, called “magnetic memory”) using magnetoresistive elements as storage elements is emerging. Since one of the characteristics of the magnetic memory is that non-destructive readout is possible, it is not necessary to write back data (refresh) every time the data is read. However, information retention time of each storage element may be in the order of months or days depending on characteristics of the storage element or on the electric current application time during writing. Therefore, some countermeasures are necessary to hold stored content for a long period.

Patent Literature 1 discloses an invention of a magnetic memory that reads data stored in a main memory and then writes back (refreshes) the data to the main memory if the number of times of reading exceeds a predetermined number of times.

### CITATION LIST

### Patent Literature

Patent Literature 1: Japanese Patent Laid-Open Publication No. 2012-22726

### SUMMARY OF INVENTION

### Technical Problem

In the technique disclosed in Patent Literature 1, to perform refresh, operation of reading out the data from the main memory and further writing back the data to the main memory is necessary in the case of the magnetic memory disclosed in Patent Literature 1, and the overhead regarding the refresh is large.

### Solution to Problem

A memory device according to an embodiment of the present invention includes: a memory chip using a magnetic memory; and a memory controller that controls read/write to the memory chip. When the memory controller receives a read request from outside the memory controller, the memory controller transmits a read command to the memory chip to read data in the memory chip. The memory controller also transmits an update command to each area of the memory chip to write back the data stored in the memory chip.

### Advantageous Effect of Invention

According to the memory device of an embodiment of the present invention, the information retention time of the memory area can be increased without sacrificing the access performance at a normal time.

### BRIEF DESCRIPTION OF DRAWINGS

FIG. 1 is a hardware configuration diagram of a storage system.

FIG. 2 is a configuration diagram of a memory chip.

FIG. 3 is a diagram describing a representative operation of a semiconductor memory.

FIG. 4 is a timing chart of a read operation.

FIG. 5 is a timing chart of a write operation.

FIG. 6 is a timing chart of an update operation.

FIG. 7 is a command truth table of the memory chip.

FIG. 8 is a configuration diagram of a cache memory package.

FIG. 9 is an explanatory view of management information included in a memory controller.

FIG. 10 is a flow chart of a periodic update process.

FIG. 11 is a flow chart of a power failure monitoring process.

FIG. 12 is a flow chart of an update process of storage information.

FIG. 13 is an explanatory view of a representative operation of the memory chip according to a second embodiment.

FIG. 14 is a timing chart in execution of an update command UAL.

FIG. 15 is a command truth table of the memory chip according to the second embodiment.

FIG. 16 is a timing chart in execution of an update command UALI.

FIG. 17 is a truth table of each command supported by the memory chip according to a third embodiment.

FIG. 18 is a flow chart of an update process of the storage information according to the third embodiment.

### DESCRIPTION OF EMBODIMENTS

Hereinafter, embodiments of the present invention will be described with reference to the drawings. Note that the embodiments described below do not limit the inventions according to the claims, and not all of the elements described in the embodiments and combinations of the elements may be required for the solution of the inventions.

Although a “program” may serve as the subject in the following description, a processor (CPU (Central Processing Unit)) actually executes the program to execute a prescribed process. However, to prevent the description from becoming redundant, the program may serve as the subject in the description. Part or all of the program may be realized by dedicated hardware. Furthermore, various programs may be installed on devices through a program distribution server or a computer-readable storage medium. Examples of the storage medium include an IC card, an SD card, and a DVD.

### First Embodiment

### (1-1) Configuration of Storage System

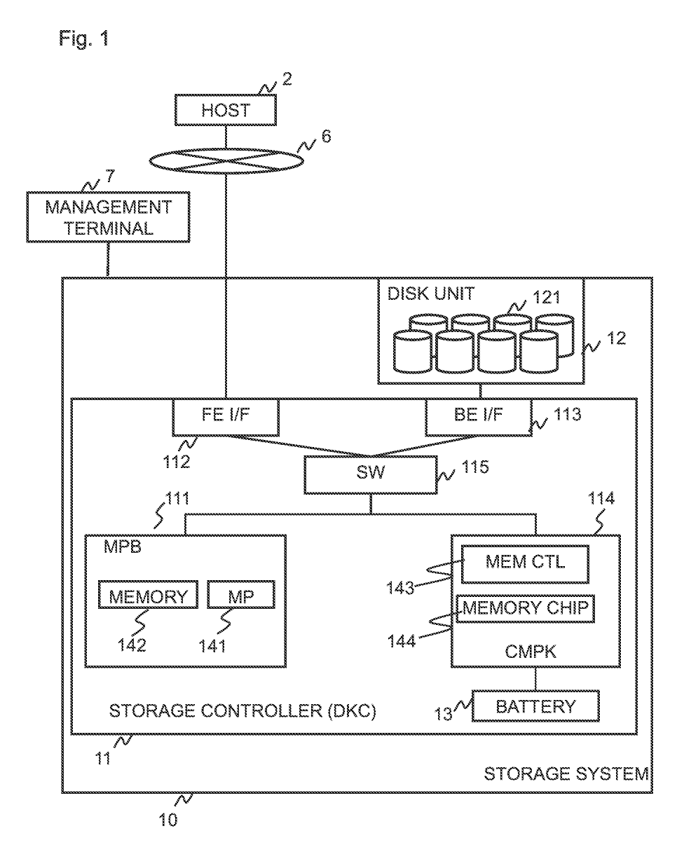

FIG. 1 shows a configuration of a storage system 10 according to an embodiment of the present invention. The storage system 10 includes a storage controller (hereinafter, abbreviated as “DKC” in some cases) 11, a disk unit 12 including a plurality of drives 121, and a battery 13. The storage controller 11 includes: an MPB 111 that is a processor board configured to control an I/O process and the like executed by the storage system 10; a front-end interface (FE I/F) 112 that is a data transfer interface between the storage controller 11 and a host 2; a back-end interface (BE I/F) 113 that is a data transfer interface between the storage controller 11 and the disk unit; and a cache memory package (CMPK) 114 for storing cache data, control data, and the like, and the constituent elements are connected to each other through a switch (SW) 115. Note that the number of constituent elements (MPB 111, FE I/F 112, BE I/F 113, CMPK 114) is not limited to the number illustrated in FIG. 1. The number of each constituent element may be two or more to increase the availability and the performance of the storage system.

Each MPB 111 includes a processor (also called MP) 141 and a local memory 142 storing a control program executed by the processor 141, control data used in the control program, and the like. The processor 141 executes a program stored in the local memory 142 to process a read/write request and the like from the host 2.

The CMPK 114 is a memory device including a memory chip 144 (abbreviated as “chip” in the drawings) and a memory controller (MEMCTL) 143 for controlling the memory chip 144. In the storage system 10 according to the present embodiment, the CMPK 114 is used as a cache memory for temporarily storing write data and the like from the host 2. The CMPK 114 is also used to store control data used by the storage system 10.

An MRAM (Magnetoresistive Random Access Memory) or an STT-RAM using magnetoresistive elements as storage elements is used for the memory chip 144 (may also be called “magnetic memory” in the present embodiment). Multiple MEMCTLs 143 and memory chips 144 may be provided.

The battery 13 is for supplying power to the CMPK 114 when there is a fault such as a power failure. Other than the battery 13, an external power supply (not shown) is connected to the storage system 10. At a normal time (when power is supplied from the external power supply), the storage system 10 uses the power supplied from the external power supply to operate. When the supply of power from the outside is ceased due to a power failure or the like, the CMPK 114 uses the power supplied from the battery 13 to execute a process necessary for maintaining the data in the storage system 10. Note that the battery 13 may be installed on the CMPK 114.

The disk unit 12 includes a plurality of drives 121, and write data from the host 2 is mainly stored in each drive 121. The drives 121 are, for example, storage devices using magnetic storage media such as HDDs. However, other storage devices, such as SSDs (Solid State Drives), may also be used.

The FE I/F 112 is an interface for transmitting and receiving data to and from the host 2 through a SAN 6. The FE I/F 112 includes a DMA controller (DMAC) for executing a process of transmitting write data from the host 2 to the CMPK 114 or transmitting data in the CMPK 114 to the host 2 based on an instruction from the MPU 141. Like the FE I/F 112, the BE I/F 113 also includes a DMAC for executing a process of transmitting data in the CMPK 114 to the drives 121 or transmitting data in the drives 121 to the CMPK 114 based on an instruction from the MPU 141.

The switch (SW) 115 is a component for mutually connecting the MPB 111, the FE I/F 112, the BE I/F 113, and the CMPK 114 and is, for example, a PCI-Express switch.

The SAN 6 is a network used for transmitting an access request (I/O request) as well as read data or write data associated with the access request when the host 2 accesses (reads/writes) the data of the storage area (volume) in the storage system 10, and the SAN 6 is a network configured by using Fibre Channel in the present embodiment. However, a configuration using another transmission medium, such as Ethernet, may be adopted.

### (1-2) Configuration of Memory Chip

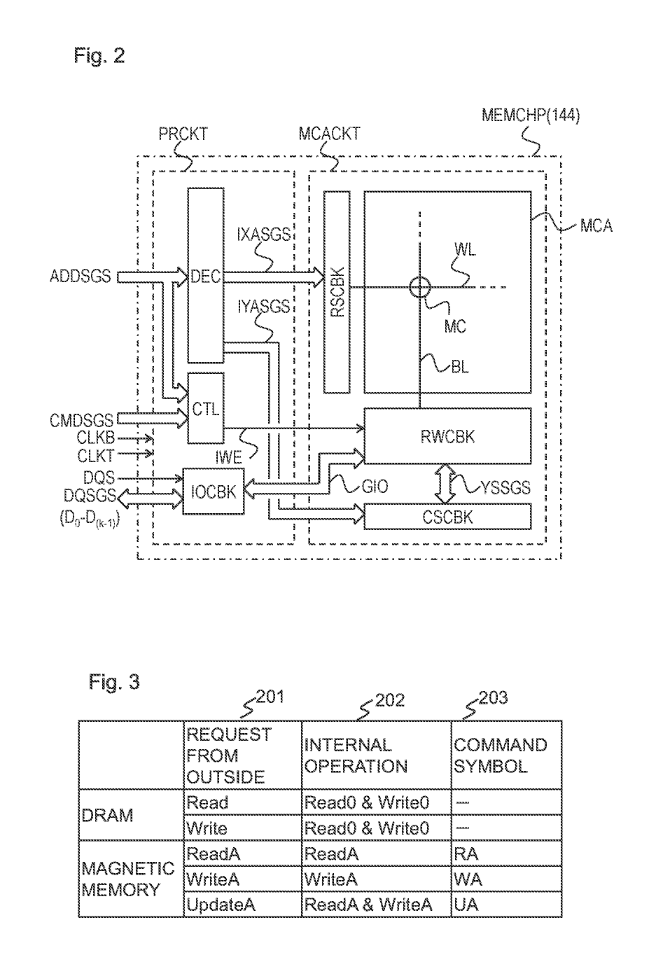

FIG. 2 is a configuration diagram of the memory chip 144 (MEMCHP) according to the present embodiment. The memory chip 144 includes a memory cell array circuit MCACKT and a peripheral circuit PRCKT.

The former memory cell array circuit MCACKT includes a memory cell array MCA, a read/write circuit group RWCBK, a row selection circuit group RSCBK, and a column selection circuit group CSCBK. The memory cell array MCA includes mxn memory cells MC arranged at intersection points of a plurality of (for example, m) word lines WL and a plurality of (for example, n) bit lines BL.

The row selection circuit group RSCBK activates one word line selected by an internal row address signal line group IXASGS described later among the m word lines WL. The column selection circuit group CSCBK activates k (≦n) bit lines selected by an internal column address signal line group IYASGS described later among the n bit lines BL.

The memory cell MC has a magnetic resistance and has a function of storing information according to the resistance value. For example, it is defined in the present embodiment that information “1” is stored when the magnetic resistance is in a low-resistance state, and information “0” is stored when the magnetic resistance is in a high-resistance state. The read/write circuit group RWCBK is arranged between the memory cell array MCA and an internal global input/output line GIO described later and is configured to read stored information from a selected memory cell or write new information to a selected memory cell according to an internal write activation signal IWE described later.

The latter peripheral circuit PRCKT includes an address decoder DEC, a controller CTL, and an input/output circuit group IOCBK. The address decoder DEC drives the internal row address signal line group IXASGS and the internal column address signal line group IYASGS according to an address signal group ADDSGS input from the outside of the memory chip 144.

The controller CTL generates a control signal, such as the internal write activation signal IWE, necessary for chip internal operation according to the address signal group ADDSGS or according to a command signal group CMDSGS. The input/output circuit group IOCBK transfers storage information between a data strobe signal DQS and the internal global input/output line GIO and between a data signal group DQSGS (D₀ to D₍ₖ₋₁₎) and the internal global input/output line GIO. Note that the operation in the memory chip 144 is performed in synchronization with system clocks CLKT and CLKB.

### (1-3) Read Operation and Write Operation of Memory Chip

FIG. 3 shows an example of a representative operation in a semiconductor memory. Here, to describe the difference between two semiconductor memories (DRAM and magnetic memory), a comparison of a request 201 from the outside of the semiconductor memory and an internal operation 202 performed in the semiconductor memory chip according to the request is illustrated.

As is well known, the DRAM includes memory cells arranged in a matrix at intersection points of a plurality of word lines and a plurality of bit lines. The memory cells include selection transistors and capacitors. The capacitor plays a role of a storage element and stores charge to store one-bit information.

Next, a read operation of the DRAM will be described. When the DRAM enters a read mode according to a request from the outside, the selection transistor in the memory cell arranged at the intersection point of the selected word line and bit line is electrically connected in the DRAM chip, and the stored charge is split between the load capacity of the bit line and the capacitor in the memory cell. As a result, a small potential difference is generated in the bit line. A sense amplifier discriminates the small potential difference to attain a read operation of desired one-bit information.

However, in the read operation of one-bit information, the split of the capacity performed above reduces the charge stored in the capacitor of the memory cell compared to before the read operation. This kind of read operation of one-bit information associated with the change in the state of the storage element is called a destructive readout operation. Therefore, the amount of charge in the memory cell needs to be recovered to a value necessary to hold the one-bit information. More specifically, an operation of writing the same information as the information read before is performed to recover the amount of stored charge to a sufficient value. Summarizing the operation, when a read request arrives from the outside of the DRAM, a write operation (Write0) of one-bit information is performed in the DRAM after a read operation (Read0) of one-bit information.

Note that in a write operation of the DRAM, the write operation (Write0) of one-bit information is performed after the read operation (Read0) of one-bit information as in the read operation described above, although there is a little difference in the timing of the input of a command signal. Here, the reason that the read operation (Read0) of one-bit information is performed is to maintain the state of the storage element in the memory cell arranged at the intersection point of the selected word line and the unselected bit line. That is, the write operation (Write0) of the same information needs to be performed after the read operation (Read0) of one-bit information in the memory cell.

Next, a write operation and a read operation of the magnetic memory will be described. The memory cell of the magnetic memory includes a selection transistor and a magnetic resistance. The magnetic resistance is used for the storage element. The resistance value changes according to the magnitude and the direction of the applied current in the write operation of one-bit information. On the other hand, the resistance value is held even when a voltage lower than a threshold set according to the characteristics of the magnetic resistance is applied or even when the power supplied to the magnetic memory chip is shut down. Therefore, in the read operation of one-bit information, the voltage lower than the threshold is applied to the magnetic resistance to discriminate the magnitude of the current flowing according to the resistance value. In this way, the physical phenomenon of storing the one-bit information is maintained, and the read operation of one-bit information of the magnetic memory is called a non-destructive readout operation.

Because of the characteristics of the non-destructive readout operation, the read operation of the magnetic memory can be completed by a read operation (ReadA) of one-bit information. Therefore, the write operation of one-bit information as in the DRAM is not necessary in the read operation of the magnetic memory. For the same reason, the write operation of the magnetic memory can also be completed by only a write operation (WriteA) of one-bit information.

The magnetic resistance used for the memory cell of the magnetic memory has characteristics that the write operation time (current application time for magnetic resistance) increases according to the information retention time, and this is illustrated in literature “Time-Resolved Reversal of Spin-Transfer Switching in a Nanomagnet,” (Koch et al., Physical Review Letters 92, 088302, 2004). Here, the information retention time denotes a maximum value of the time that the information stored in the storage area can be held. When a time equal to or more than the information retention time has passed since the storage of the information in the storage area, the content of the information stored in the storage area may be changed.

The information retention time is short in the magnetic memory in which the write operation time is reduced to increase the performance. For example, the information retention time may be in the order of months or days. The storage system 10 according to the present embodiment uses the magnetic memory as a cache memory of the storage controller. When the information retention time of the magnetic memory is in the order of months or days, the information in the magnetic memory may be lost before the storage controller 11 accesses the information stored in the magnetic memory again. This is equivalent to a loss of data stored by the user.

To solve the problem, the storage system 10 according to the present embodiment periodically reads the data stored in the memory chip 144 and writes back the read data again to the same memory cell. Therefore, the memory chip 144 according to the present embodiment includes an operation mode called UpdateA, in addition to operation modes ReadA and WriteA. The UpdateA is an operation mode of performing the read operation ReadA and performing the write operation WriteA for writing back the read information again to the same memory cell. Note that in the present specification, the operation of writing back the information read in the read operation ReadA again to the same memory cell will be called an “update operation”. A command symbol 203 of FIG. 3 indicates an abbreviation of a command used for instructing the memory chip 144 to perform the read operation ReadA, the write operation WriteA, or the update operation UpdateA from the outside.

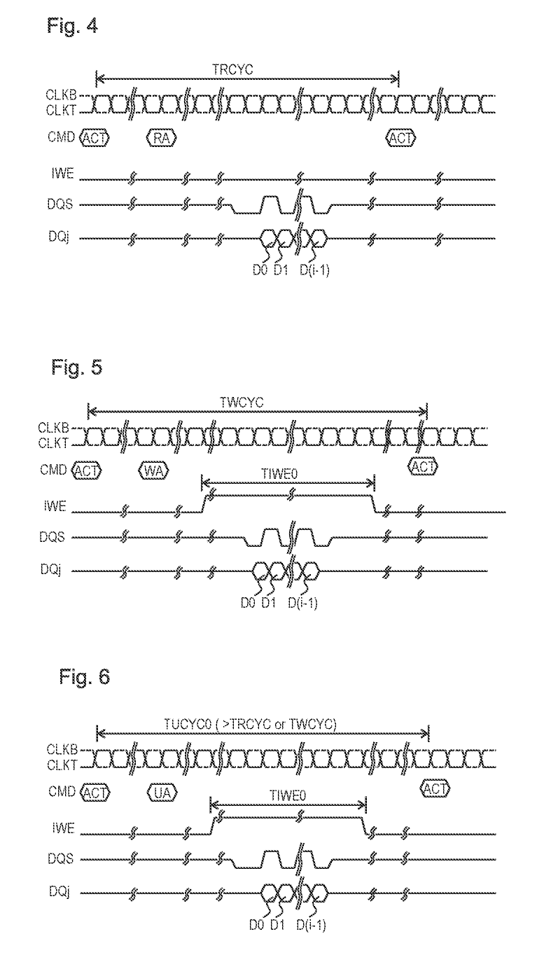

FIG. 4 shows a timing chart of the read operation performed in the memory chip 144 according to the present embodiment. The operation corresponds to the read operation ReadA described in FIG. 3, and FIG. 4 illustrates an example of the read operation with a burst length i.

First, an active command ACT is input to the controller CTL from the outside (MEMCTL 143) of the memory chip 144. After a predetermined clock cycle time, a read command RA is input. The internal write activation signal IWE is maintained in an inactive state (here, logical value 0), and the stored information in the memory cell MC is read to a data pin DGⱼ in synchronization with the data strobe DQS signal. Subsequently, the memory chip 144 returns to a waiting state within a predetermined clock cycle time and enters a state in which the following active command ACT can be received. Here, a shortest allowable interval in receiving consecutive active commands will be called an operation cycle time. In FIG. 4, TRCYC indicates the operation cycle time during reading.

FIG. 5 shows a timing chart of the write operation performed in the memory chip 144 according to the present embodiment. The operation corresponds to the write operation WriteA described in FIG. 3, and FIG. 5 illustrates an example of the write operation with the burst length i.

First, the active command ACT is input to the controller CTL from the outside (MEMCTL 143) of the memory chip 144. After a predetermined clock cycle time, a write command WA is input. The internal write activation signal IWE is shifted to an active state according to the input of the command WA, and the logical value of 1 is held for an internal write activation time TIWE0 to write the information input to the data pin DQⱼ from the outside to the memory cell MC. Subsequently, the memory chip 144 returns to the waiting state within a predetermined clock cycle time and enters the state in which the following active command ACT can be received. An operation cycle time TWCYC in the write operation may be longer than TRCYC. Furthermore, it is desirable that TWCYC is equal to or shorter than the write operation cycle time of an existing DRAM.

FIG. 6 is a timing chart of the update operation performed in the memory chip 144 according to the present embodiment. The operation corresponds to the update operation UpdateA described above, and FIG. 6 illustrates an example of the update operation with the burst length i. First, the active command ACT is input, and a command UA (update command) is input after a predetermined clock cycle time. The internal write activation signal IWE is shifted to the active state according to the input of the command UA, and the logical value of 1 is held for the internal write activation time TIWE0 to perform the write operation WriteA following the read operation ReadA.

In the write operation WriteA, the stored information held by the buffer in the read/write circuit group RWCBK is written after the stored information is read in the read operation ReadA. Subsequently, the memory chip 144 returns to the waiting state within a predetermined clock cycle time and enters the state in which the following active command ACT can be received. A shortest allowable interval in receiving the following active command after the reception of the active command ACT of the update operation will be called an update operation cycle time. FIG. 6 illustrates an update operation cycle time TUCYC0. The value TUCYC0 is larger than the operation cycle time TRCYC shown in FIG. 4 or TWCYC, because the write operation WriteA is added.

### (1-4) Commands

Next, commands to be input to the memory chip 144 from the outside to execute the update operation described above will be described. In the memory chip 144 according to the present embodiment, the chip interface is common with the DDR specification used in the DRAM as much as possible. This is because the magnetic memory, such as an MRAM, is often researched and developed as a successor memory of the existing DRAM, and the magnetic memory is more suitable for replacing the existing DRAM when the chip interface is in common with the existing DRAM. However, the update operation (UpdateA) described above is an operation mode not provided in the existing DRAM, and a new update command is added to the DDR specification to support the update operation.

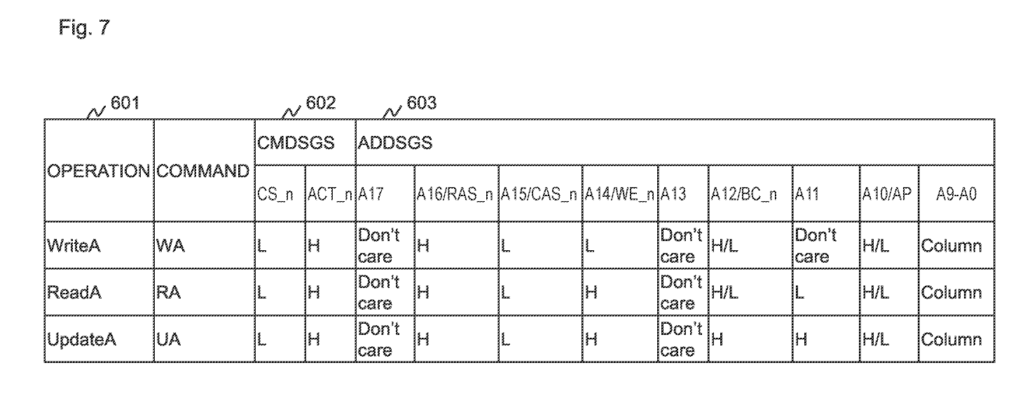

FIG. 7 shows a command truth table in the memory chip 144 according to the present embodiment. The update command UA, the write command WA, and the read command RA are illustrated in the command truth table. In FIG. 7, the name of each pin follows the specification of a DDR4 SDRAM.

A chip select signal CS_n and an activation command signal ACT_n (602) are constituent elements of the command signal group CMDSGS in FIG. 2. In addition, address signals A0 to A17 (603) are constituent elements of the address signal group ADDSGS in FIG. 2. Among these, the address signal A16 serves as an RAS_n signal, the address signal A15 serves as a CAS_n signal, the address signal A14 serves as a WE_n signal, the address signal A12 serves as a BC_n signal, and the address signal A10 serves as an AP signal.

In the memory chip 144 according to the present embodiment, A17, A13, and A11 which are undefined in the read command of the DRAM are used to define the update command UA. More specifically, the update command UA is defined as (A17, A13, A11)=(Don't care, Don't care, H). Meanwhile, in accordance with the definition of the update command, the address signals in the read command RA of the memory chip 144 is redefined as (A17, A13, A11)=(Don't care, Don't care, L). The write command WA is the same as in the DRAM.

Defining the commands in this way allows the memory chip 144 to utilize existing pins used in the DRAM. Therefore, a reduction in the implementation cost can be expected.

Note that the method of defining the commands is not limited to the method described above. A realization method other than the method described above is also possible. An example of an alternative method includes a method of allocating an unused pin in an unconnected state in an existing DRAM to a control signal for exchanging the update command. The signal is also a constituent element of the command signal group CMDSGS shown in FIG. 2. When the method is adopted, the existing pin is also utilized while the compatibility with the DRAM is maintained, and a reduction in the implementation cost can be expected.

Another example of the method includes a method of physically changing the chip interface of the existing DRAM. For example, a method of adding a control signal pin for exchanging the update command to the memory chip 144 may also be adopted.

### (2-1) Configuration of Cache Memory Package

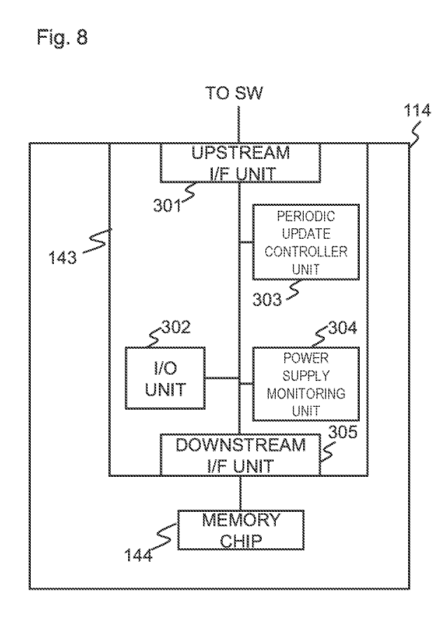

Next, a configuration of the CMPK 114 will be described with reference to FIG. 8. The CMPK 114 includes the memory controller (MEMCTL) 143 and the memory chip 144. Although a plurality of MEMCTLs 143 and/or a plurality of memory chips 144 may be provided, an example in which the CMPK 114 includes one MEMCTL 143 and one memory chip 144 will be mainly described below. Furthermore, the method of mounting the memory chip 144 on the CMPK 114 is not limited to a specific method. For example, one or a plurality of memory chips 144 may be directly arranged and mounted on a substrate of the CMPK 114. Alternatively, one or a plurality of memory chips 144 may be memory modules, such as well-known DIMMs (Dual Inline Memory Modules), and the memory modules may be connected to sockets provided on the substrate of the CMPK 114 to mount the memory chips 144 on the CMPK 114.

The MEMCTL 143 includes functional blocks of an upstream I/F unit 301, an I/O unit 302, a periodic update controller unit 303, a power supply monitoring unit 304, and a downstream I/F unit 305. Each functional block is implemented by hardware such as an ASIC (Application Specific Integrated Circuit). However, a plurality of functional blocks may be implemented by one ASIC.

In addition, not all functions need to be realized by hardware. A processor and a memory may be provided on the MEMCTL 143, and the processor may execute a predetermined program so that the processor can operate as the I/O unit 302, the periodic update controller unit 303, and the like.

The upstream I/F unit 301 is an interface for communicating with external devices (for example, the SW 115 of the storage controller 11 and the MP 141 connected through the SW 155). Meanwhile, the downstream I/F unit 305 is an interface for connecting the MEMCTL 143 and the memory chip 144.

The I/O unit 302 is a functional block that controls reading of data from the memory chip 144 and writing of data to the memory chip 144 according to an access request from the MP 141 or the like coming through the SW 115 and the upstream I/F unit 301. The I/O unit 302 also has a function of generating an ECC (Error Correcting Code) and a function of using the ECC to detect and correct an error.

When the I/O unit 302 receives a write request and data to be written from an external device through the upstream I/F unit 301, the I/O unit 302 generates the ECC (Error Correcting Code) from the data to be written and adds the ECC to the data to be written. The I/O unit 302 then writes the data to be written provided with the ECC to the memory chip 144. In the writing to the memory chip 144, the I/O unit 302 issues the write command WA described above to the memory chip 144.

Conversely, when the I/O unit 302 receives a read request from an external device through the upstream I/F unit 301, the I/O unit 302 reads the data provided with the ECC from the memory chip 144. In the reading from the memory chip 144, the I/O unit 302 issues the read command RA described above to the memory chip 144. After reading the data provided with the ECC from the memory chip 144, the I/O unit 302 uses the ECC to detect an error (hereinafter, this error detection will be called “ECC check”). Specifically, the I/O unit 302 calculates the ECC from the read data and compares the calculated ECC with the ECC added to the data to check whether the data includes an error.

If the calculated ECC does not coincide with the ECC added to the data, the I/O unit 302 can determine that the data includes an error. In this case, the I/O unit 302 uses the ECC to correct the data and returns the corrected data to the read request source (for example, external device such as MP 141) through the upstream I/F unit 301.

Although the data is provided with the ECC and stored in the memory chip 144, the data and the ECC may not be stored adjacent to each other. For example, when the CMPK 114 includes a plurality of (for example, n) memory chips 144, and write data received from the outside is distributed and stored in the plurality of memory chips 144, the data may be written in (n−1) memory chips 144, and the ECC generated from the data stored in the (n−1) memory chips 144 may be stored in one memory chip 144.

The periodic update controller unit 303 is a functional block that periodically reads the data stored in the memory chip 144 and that writes back the read data again to the same memory cell. Hereinafter, the process of periodically reading the data stored in the memory chip 144 and writing back the data again to the same memory cell will be called a periodic update process.

### (2-2) Periodic Update Process

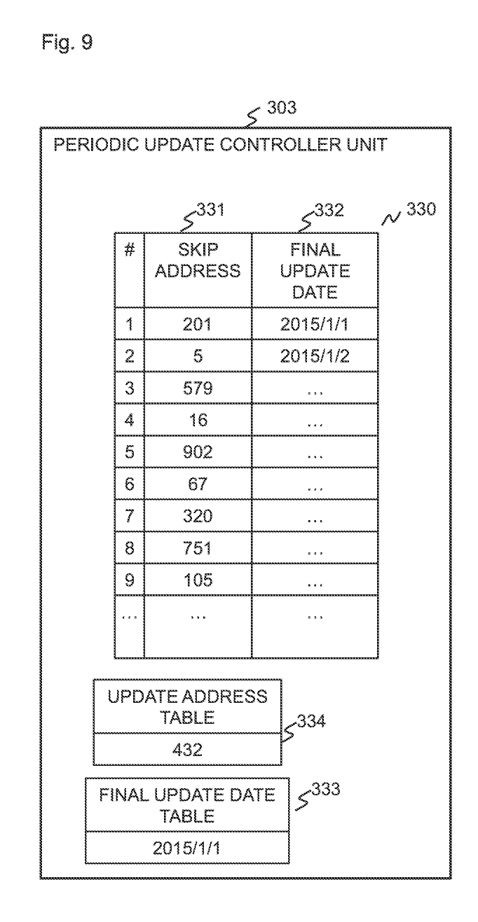

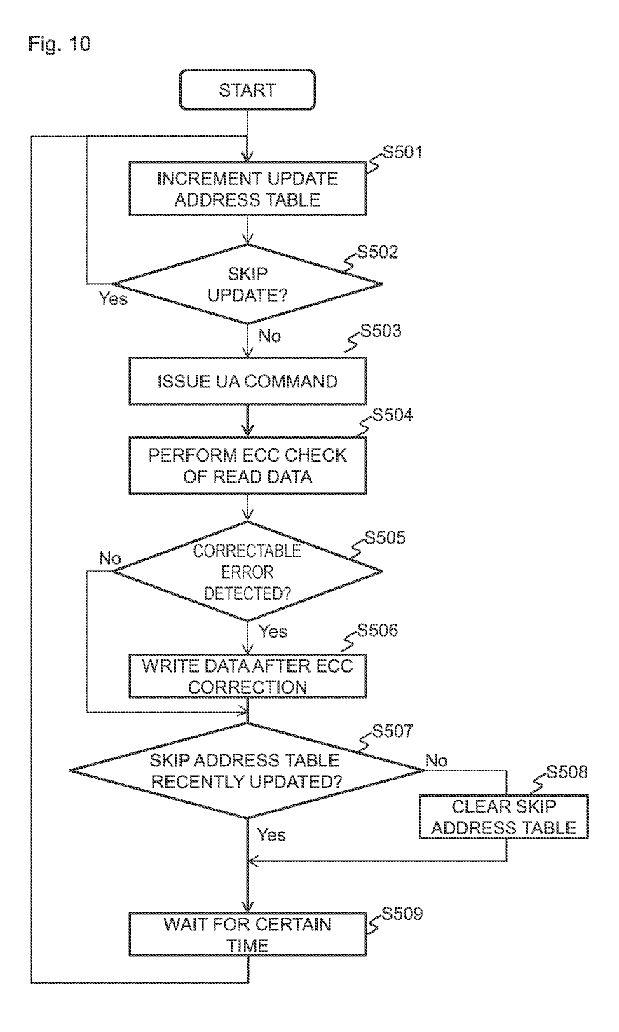

The periodic update process will be described with reference to FIGS. 9 and 10. First, management information used by the periodic update controller unit 303 for the periodic update process will be described. The periodic update controller unit 303 includes a skip address table 330, an update address table 334, and a final update date table 333 that are storage areas of the management information (FIG. 9).

The update address table 334 is a storage area that can store one address of an area on the memory chip 144. The update address table 334 stores the address of an area on the memory chip 144 to be updated when the periodic update controller unit 303 executes the periodic update process. An initial value of −1 is stored.

The periodic update controller unit 303 increments the value stored in the update address table 334 when the update process of the area on the memory chip 144 corresponding to the address stored in the update address table 334 is finished. However, if the value of the update address table 334 is greater than an end address of the memory chip 144 as a result of the increment, the value of the update address table 334 is set to 0. In this way, the value of the update address table 334 is changed in each periodic update process, and the update process is sequentially executed from a head area of the memory chip 144 in the periodic update process. After the execution of the update process of an end area of the memory chip 144, the update process is sequentially executed again from the head area of the memory chip 144.

The skip address table 330 includes columns of a skip address 331 and a final update date 332. The address of an area on the memory chip 144 is stored in each field of the column of the skip address 331. In addition, the I/O unit 302 stores the addresses in the skip address table 330. When the I/O unit 302 receives a write request from the upstream I/F unit 301, the I/O unit 302 writes the data to the memory chip 144 and registers, in the skip address table 330, the address of the area on the memory chip 144 in which the data is written. Each field of the skip address 331 stores an invalid value (value invalid as an address of the memory chip 144, such as −1) in the initial state.

Note that the number of addresses that can be stored in the column of the skip address 331, that is, the number of rows provided in the skip address table 330, is smaller than the number of all addresses of the memory chip 144. Although the number of rows provided in the skip address table 330 may be the same as the number of all addresses of the memory chip 144, the size of the skip address table 330 is large in that case, and the cost increases. Therefore, the number of rows provided in the skip address table 330 is set to a number smaller than the number of all addresses of the memory chip 144.

A flow of a process of registering the address in the skip address table 330 in response to the reception of the write request from the upstream I/F unit 301 by the I/O unit 302 will be described. When there is a field storing the invalid value in the column of the skip address 331, the I/O unit 302 registers the address in the field. When there is no field storing the invalid value in the column of the skip address 331, the I/O unit 302 registers the address by writing the address provided with the data over the field of the address to be updated last in the periodic update process among the plurality of addresses registered in the column of the skip address 331. When the address is registered in the skip address 331, the I/O unit 302 stores the date of the registration of the address in the final update date 332 of the row in which the address is registered. Although the date is stored in the final update date 332 in the example described here, the time may also be stored in addition to the date.

An outline of an example of a method of determining the address to be updated last in the periodic update process according to the present embodiment will be described. Note that the end address of the memory chip 144 will be defined as M, and the address stored in the update address table 334 will be defined as U. The number of addresses that can be stored in the skip address table 330 will be written as n, and the address stored in a k-th (1≦k≦n) row of the skip address table 330 will be written as Sₖ.

First, a distance (will be written as Dₖ) between the address U stored in the update address table 334 and the address Sₖ stored in the skip address table 330 is calculated. The distance Dₖ here is a value calculated by the following formulas.

Dₖ=Sₖ−U (when Sₖ>U)

Dₖ=M+Sₖ−U (When Sₖ≦U)

Distances D₁ to Dₙ are calculated based on the formulas, and then a maximum value of D₁ to Dₙ is obtained. If the maximum value is Dₘ (1≦m≦n), Sₘ is determined to be the address to be updated last. Therefore, the I/O unit 302 writes the address over the field storing Sₘ in the column of the skip address 331.

Next, a processing flow of the periodic update process executed by the periodic update controller unit 303 will be described with reference to FIG. 10. Note that “S” added to the head of the reference numerals in FIG. 10 denotes a “step”.

(S501) The periodic update controller unit 303 adds 1 to the value of the update address table 334. However, when the value of the update address table 334 exceeds the end address of the memory chip 144 as a result of the addition, the periodic update controller unit 303 sets the value of the update address table 334 to 0. Note that the value of the update address table 334 will be written as U.

(S502) The periodic update controller unit 303 determines whether the skip address table 330 includes the same value as U. If the same value as U is included (S502: Yes), the periodic update controller unit 303 does not execute the update process of the address U and returns to step 501.

(S503) If the same value as U is not included in the skip address table 330 (S502: No), the periodic update controller unit 303 issues the update command UA to the memory chip 144 through the downstream I/F unit 305 in order to execute the update process of the address U. In this case, the periodic update controller unit 303 inputs a signal to each pin of the memory chip 144 according to the command truth table described above.

(S504) When the update command UA is issued to the address U of the memory chip 144, the data stored in the address U is read, and the read data is written back again to the area of the address U and sent back to the MEMCTL 143. The ECC is added to the data. The periodic update controller unit 303 performs the ECC check of the read data.

(S505) The periodic update controller unit 303 determines whether a correctable error is detected in the ECC check of S504. If the correctable error is not detected, S507 is executed next. On the other hand, if the correctable error is detected, a process of S506 is executed.

(S506) The periodic update controller unit 303 uses the ECC to correct the read data and writes back the corrected data to the address U of the memory chip 144. Subsequently, a process of S507 is executed.

(S507) The periodic update controller unit 303 calculates the difference between the date information stored in the final update date 332 in each row of the skip address table 330 and the current date. The periodic update controller unit 303 then judges whether there is a row in which the difference exceeds a predetermined threshold. If there is no row exceeding the predetermined threshold, this indicates that the area of the memory chip 144 corresponding to each address (skip address 331) registered in the skip address table 330 is updated relatively recently (within a predetermined time) by the I/O unit 302. In this case, S509 is executed next. On the other hand, if there is a row in which the difference exceeds the predetermined threshold, this indicates that the area of the memory chip 144 corresponding to the skip address 331 of the row is not updated for more than the predetermined time. In this case, a process of S508 is executed next.

(S508) The periodic update controller unit 303 clears (deletes) the skip address 331 and the final update date 332 stored in the skip address table 330. Specifically, if the periodic update controller unit 303 determines that the difference between the date information of the final update date 332 registered in an s-th row of the skip address table 330 and the current date exceeds the predetermined threshold in the determination of S507, the periodic update controller unit 303 stores invalid values in the skip address 331 and the final update date 332 of the s-th row.

(S509) The periodic update controller unit 303 waits for a certain time. After the certain time, the periodic update controller unit 303 repeats the process from S501.

The periodic update process has been described. As described above, the longer the write operation time of the magnetic memory, the longer the information retention time of the magnetic memory. However, the write operation time needs to be reduced when the access performance of the magnetic memory is to be improved. In this case, the information retention time may become short. When the areas of the magnetic memory are updated in a period shorter than the information retention time (when the frequency of access is high), the short information retention time is not much of a problem (note that the “update” here also includes the writing process based on the write command WA in addition to the update process based on the update command UA). However, in the memory areas not updated within the information retention time, the possibility of loss of information becomes high.

In the storage system 10 according to the present embodiment, all areas of the memory chip 144 are periodically updated in the periodic update process described above, and the loss of information in the memory chip 144 can be prevented. Conversely, it is desirable to set the waiting time of S509 to a value such that all areas of the memory chip 144 are updated within the information retention time. If the waiting time of S509 is too short, the update process is frequently applied to all areas of the memory chip 144. This obstructs the I/O request from the outside (such as MP 141) carried out by the I/O unit 302. If the waiting time of S509 is too long, there may be areas in which the update process is not executed within the information retention time. Therefore, it is desirable to set the waiting time such that the process by the I/O unit 302 is not obstructed, and the update process is applied to each area of the memory chip 144 within the information retention time.

When the update process is applied to the area of the memory chip 144 in the periodic update process, the update command UA is issued to the memory chip 144, and the data stored in the area is read out to the MEMCTL 143 in response to the issue. Since the MEMCTL 143 performs the ECC check of the read data, it can write back the corrected data when there is an error in the stored data.

As described above, the update process is not applied to the addresses registered in the skip address table 330 among the areas of the memory chip 144 in the periodic update process (S502). Addresses for which writing is recently requested from the outside (such as MP 141) are registered in the skip address table 330. Therefore, the addresses registered in the skip address table 330 are areas in which not much time has passed since the update and are areas in which it is less necessary to rewrite data in the update process. Therefore, the update process is not applied to the addresses registered in the skip address table 330 in the periodic update process according to the present embodiment, and the efficiency of the periodic update process is increased.

However, after the addresses are registered once in the skip address table 330, writing may not be performed for the addresses for a long period. An example of such a case includes a case in which a write request does not arrive at all from the outside of the CMPK 114 for a long period (period exceeding the information retention time of the memory chip 144). In this case, the addresses (skip addresses 331) registered in the skip address table are not updated at all. Although the execution of the periodic update process is continued even in this state, the update process is not applied to the addresses registered in the skip address table 330. Therefore, the update process may not be applied to the addresses registered in the skip address table 330 even after the information retention time has passed.

To prevent this, when the I/O unit 302 registers the address in the skip address table 330, the I/O unit 302 stores, in the final update date 332, the information of the date of the registration of the address along with the address. In the course of the periodic update process, the periodic update controller unit 303 deletes the skip address 331 of the row in which the difference between the current date and the final update date 332 exceeds a predetermined threshold (S507, S508). This prevents the areas on the memory chip 144 corresponding to the addresses registered in the skip address table 330 from not being updated even after the information retention time elapsed.

Although the periodic update controller unit 303 deletes the skip addresses 331 of only the rows in which the difference between the current date and the final update date 332 exceeds the predetermined threshold in the example described above, the periodic update controller unit 303 may delete the entire content of the skip address table 330 when the write request does not come at all from the outside of the CMPK 114 for a long period. An outline of the process in this case will be described below.

The periodic update controller unit 303 can provide the final update date table 333 (FIG. 9) that can register one piece of date information, instead of providing the field for storing the final update date 332 in each row of the skip address table 330. The I/O unit 302 then registers, in the final update date table 333, the date (or day and time) of the writing process most recently executed by the I/O unit 302.

The periodic update controller unit 303 judges whether the difference between the date stored in the final update date table 333 and the current date exceeds a predetermined threshold in S507. If the difference exceeds the predetermined threshold, the periodic update controller unit 303 can clear the entire content (store invalid values) of the skip address table 330. In this way, the storage capacity for storing the date information by the periodic update controller unit 303 can be reduced, and the judgement process in S507 can be simplified.

### (3-1) During Power Failure

The processes described so far are processes executed when the power is supplied to the storage system 10 and the CMPK 114 from the external power supply. A process executed by the CMPK 114 when the supply of power from the outside is stopped will be described below.

Examples of representative factors that the power supply of the cache memory installed on the storage system 10 is shut down include the following three factors. The first is a power shutdown systematically performed when the work using the storage system 10 is finished. The power shutdown will be called planned outage in the present specification. The second is a power shutdown suddenly and locally performed to prevent the spread of the effect of a fault when there is a fault in the CMPK 114 or another constituent element. The third is a sudden power shutdown when there is a fault in a system of an external power supply that supplies power to the storage system 10 or in a power supply system inside of the storage system 10. Hereinafter, these will be collectively called a power failure. In the storage system 10, permanent storage of information is demanded even when there is a power failure.

In a conventional storage system, a DRAM is used for the cache memory. The DRAM can store information only in an energized state. Therefore, the storage system copies the data stored in the DRAM to an HDD or an SSD upon the power failure to prevent a loss of information. Here, when there is a sudden power shutdown described in the second and third factors, the conventional storage system copies the data by using an auxiliary power supply system including a storage battery or a large-capacity capacitor.

On the other hand, the information in the cache memory is kept during the power failure in a storage system using a magnetic memory for the cache memory (CMPK 114) as in the storage system 10 according to the present embodiment. However, the periodic update process described above cannot be executed during the power failure period. Therefore, for example, an update operation of all areas of the memory chip 144 is performed just before the power shutdown upon the planned outage, and the power of the battery 13 is used to perform the update operation of all areas of the memory chip 144 when a sudden power shutdown occurs. As a result, the information retention time of each memory area under a power failure can be extended.

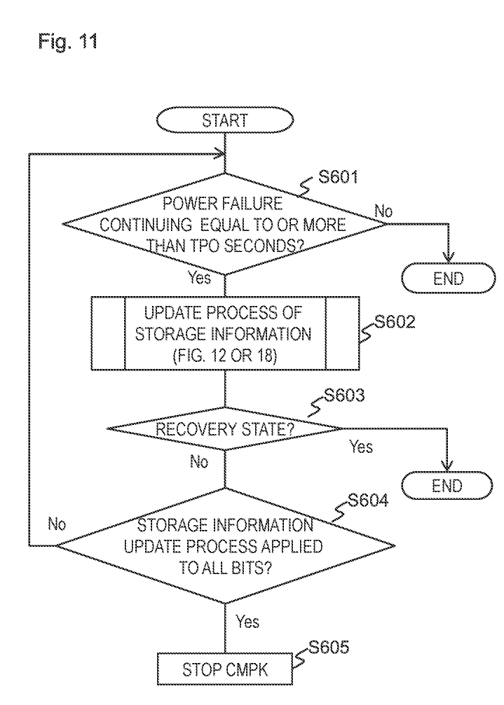

FIG. 11 shows a flow of a power failure monitoring process. The process is executed by the power supply monitoring unit 304 when the supply of power from the external power supply to the CMPK 114 is ceased. In this case, the power supplied from the battery 13 is used to execute the process.

When the power failure monitoring process is started, the power supply monitoring unit 304 judges whether time equal to or more than a preset time (the time will be called TPO, and the unit of TPO is second) has elapsed since the cease of the supply of power from the external power supply (S601). If the elapsed time is less than TPO seconds (S601: No), the process ends. If the power failure state is continuing equal to or more than TPO seconds, an update process of the storage information is executed (S602).

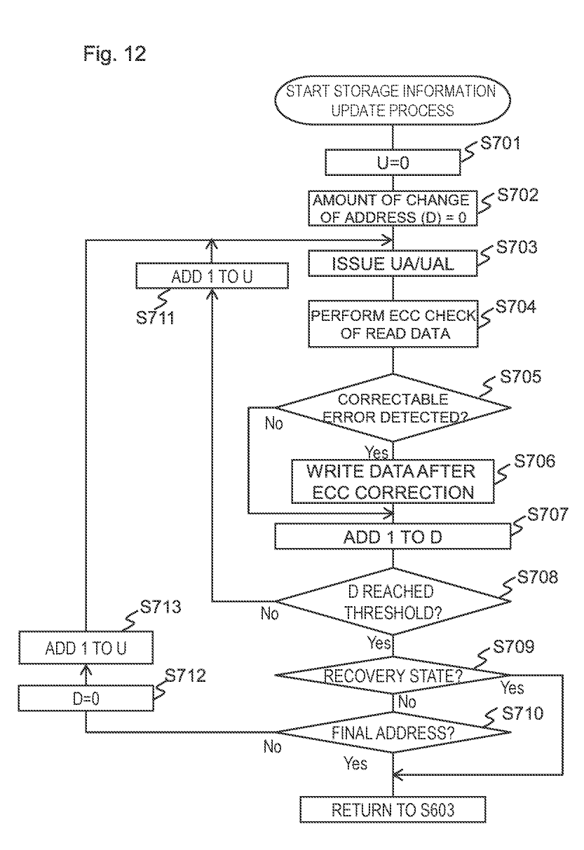

A flow of the update process executed in S602 will be described with reference to FIG. 12.

The power supply monitoring unit 304 includes areas for storing an address value of the memory area to be updated and an amount of change of the address. The former will be written as U, and the latter will be written as D. First, the power supply monitoring unit 304 sets U to a head address (that is, 0) of the memory chip (S701) and sets D to 0 (S702).

Next, the power supply monitoring unit 304 applies the update process to the area of the address U (S703). As in S503, the power supply monitoring unit 304 here issues the update command UA to the memory chip 144. Then, power supply monitoring unit 304 performs the ECC check of the data read from the memory chip 144 (S704). If a correctable error is detected (S705: Yes), the power supply monitoring unit 304 uses the ECC to correct the data and then writes the corrected data to the area of the address U (S706). The write command WA is used to write the corrected data.

Next, the power supply monitoring unit 304 adds 1 to D (S707). If the D is smaller than a preset threshold (S708: No), the power supply monitoring unit 304 adds 1 to U (S711) and continues the update process for the memory area of the following address (S703). If D reaches the threshold, the power supply monitoring unit 304 checks the state of the power supply system (S709). If the power supply system is in a recovery state (state in which the supply of power from the external power supply is restarted) (S709: Yes), the power supply monitoring unit 304 executes a process of step S603 and subsequent steps of the caller. Although the process of S603 and subsequent steps will be described later, the power failure monitoring process ends in this case. That is, in the update process of FIG. 12, the state of power supply from the external power supply is checked every time a predetermined number of areas of the memory chip 144 are updated. When the supply of power from the external power supply is restarted, the power failure monitoring process is interrupted, and the operation of the storage system 10 is continued.

On the other hand, if the power failure state is continuing (S709: No), the power supply monitoring unit 304 judges whether the address U is equal to a final address of the memory chip 144 (S710). If the address U is smaller than the final address of the memory chip 144 (S710: No), the power supply monitoring unit 304 sets the value of D to 0 (S712), adds 1 to U (S713), and repeats the process again from S703. If the address U is equal to the final address of the memory chip 144 (S710: Yes), S603 is executed.

Back to the description of the flow of FIG. 11, if the power supply system is in the recovery state in S603, the power supply monitoring unit 304 ends the power failure monitoring process and continues the operation of the storage system. If the power failure state is continuing, and the storage information update process is applied to all areas of the memory chip 144 (S604: Yes, the power supply monitoring unit 304 stops the CMPK 114. If the power failure state is continuing, but the storage information update process is not completed for all areas of the memory chip 144 (S604: No), the power supply monitoring unit 304 executes the process of S601 and subsequent steps again.

The storage system according to the first embodiment has been described. As described above, the longer the write operation time (current application time during writing) of the magnetic memory is, the longer the information retention time of the magnetic memory tends to be. Therefore, it is desirable to increase the write operation time to prevent a loss of information. However, an increase in the write operation time reduces the access performance of the memory.

In the storage system according to the first embodiment, the memory controller (periodic update controller unit) of the cache memory package issues the update command to each memory area on the memory chip to periodically rewrite the data to each memory area, and the information retention time of each memory area can be extended. Therefore, the loss of information can be prevented without the writing with a long write operation time in the writing of the data requested from the outside of the cache memory package.

In the cache memory package according to the first embodiment, when the memory controller issues the update command to the memory area on the memory chip, rewrite of the data to the memory area is performed, and the data stored in the memory area is read out to the memory controller. The memory controller includes error detection/correction means of data, and the error detection/correction means detects an error of the read data. If the data includes an error, the memory controller can correct the data and write back the data to the memory area.

To perform only the error detection of the data stored in the memory area, there can be a method of providing the error detection/correction means in the memory chip instead of providing the error detection/correction means on the memory controller. However, when the memory chip is used in an information processing system, such as the storage system according to the present embodiment, an error that may occur on a data transmission path from the memory chip to the memory controller needs to be detected and corrected, and it is necessary to install the error detection/correction means on the memory controller. Therefore, the implementation cost of the cache memory package and the storage system can be reduced by performing the error detection and correction in the memory controller without providing the error detection/correction means on the memory chip.

### Second Embodiment

Next, a second embodiment will be described. The hardware configuration of the storage system according to the second embodiment is the same as in the storage system according to the first embodiment. The memory chip 144 that supports the update command UA for executing the update process of the memory area is described in the first embodiment. It is also described that the memory controller 143 periodically applies the update process to each area of the memory chip 144 to reduce the risk of a loss of data.

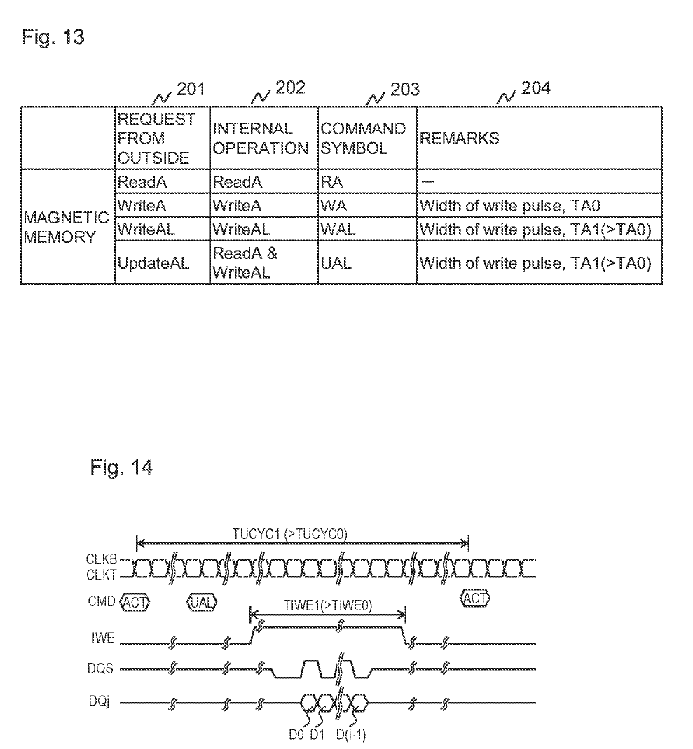

FIG. 13 shows a summary of operation supported by the memory chip 144 according to the second embodiment. There are two differences from the memory chip 144 according to the first embodiment. A first difference is that two write operations WriteA and WriteAL are included. The former write operation WriteA is used in the execution of normal writing (that is, when there is a write request from the outside of the CMPK 114). In this case, the internal write activation signal IWE is activated for the internal write activation time TIWE0 as shown in FIG. 5, and a write current with a pulse width TA0 is applied to perform a write operation to the memory cell. On the other hand, the latter long time write operation WriteAL is used to rewrite the storage information in which the correctable error is corrected. In this case, the internal write activation signal IWE is activated for an internal write activation time TIWE1 (>TIWE0) longer than the normal write operation, and a write current with a pulse width TA1 (>TA0) longer than the normal write operation is applied to perform a write operation to the memory cell. The write operation time of the long time write operation WriteAL is longer than in the write operation WriteA, and an increase in the information retention time of the storage area can be expected compared to when the storage information is written by the write operation WriteA.

A second difference is that the long time write operation WriteAL is also performed during writing in the update operation. FIG. 14 shows a timing chart in execution of a long time update operation UpdateAL. In the long time update operation UpdateAL, writing to write back the read information is performed after the read operation ReadA as in the update operation described in the first embodiment. However, the long time write operation WriteAL is performed in the writing here. Therefore, an update operation cycle time TUCYC1 is longer than TUCYC0 shown in FIG. 6. Since the long time write operation and the long time update operation are used in addition to the normal write operation, the information retention time of the magnetic memory can be further increased while processing the system provided with the magnetic memory at a highest performance.

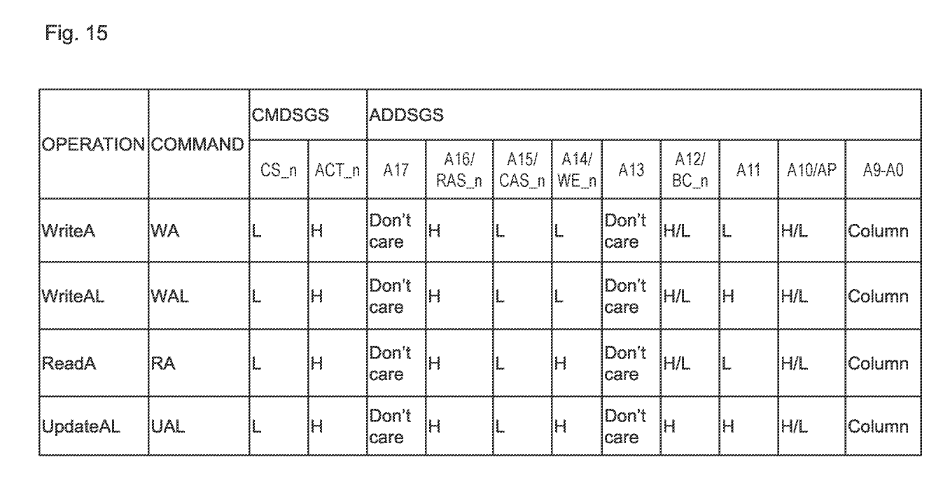

In the present embodiment, a command for instructing the memory chip 144 to execute the long time write operation WriteAL will be called a “write command WAL”. A command for instructing the memory chip 144 to execute the long time update operation UpdateAL will be called an “update command UAL”. FIG. 15 shows an example of a command truth table of commands supported by the memory chip 144 according to the second embodiment. In the memory chip 144 according to the second embodiment, the commands are also defined in compliance with the DDR4 specification. FIG. 15 shows an example of using the address signals A11 and A14 (WE_n) to define four commands. That is, the definition is as follows.

Read command RA: (A14, A11)=(H, L)

Write command WA: (A14, A11)=(L, L)

Write command WAL: (A14, A11)=(L, H)

Update command UAL: (A14, A11)=(H, L)

Next, functions of the CMPK 114 in the storage system according to the second embodiment will be described. As in the CMPK 114 according to the first embodiment, the CMPK 114 according to the second embodiment includes the upstream I/F unit 301, the I/O unit 302, the periodic update controller unit 303, the power supply monitoring unit 304, and the downstream I/F unit 305. The functions of the upstream I/F unit 301, the I/O unit 302, and the downstream I/F unit 305 are the same as the functions described in the first embodiment. The periodic update controller unit 303 and the power supply monitoring unit 304 also execute the periodic update process and the power failure monitoring process, respectively, as described in the first embodiment. The difference from the first embodiment is that the long time update operation UpdateAL and the long time write operation WriteAL are used to write the data in the periodic update process and the power failure monitoring process. There is no difference in other points, and flows of the periodic update process and the power failure monitoring process in the second embodiment will be described with reference to FIGS. 10 and 12.

First, the periodic update process in the second embodiment will be described with reference to FIG. 10. The periodic update controller unit 303 according to the first embodiment issues the update command UA to the memory chip 144 in S503 and issues the write command WA to the memory chip 144 in S506. The periodic update controller unit 303 according to the second embodiment issues an update command UAL command to the memory chip 144 in S503 and issues a write command WAL command to the memory chip 144 in S506 to increase the write time in the update process. The other points are the same as in the description of the first embodiment. Therefore, the information retention time of the memory area updated in the periodic update process can be increased.

In the writing to the memory chip 144 at the normal time performed by the I/O unit 302, such as writing of data when a write request is received from the MP 141, the CMPK 114 according to the second embodiment issues the write command WA to the memory chip 144 as in the first embodiment. Therefore, the time required for the writing of data at the normal time is not different from the CMPK 114 according to the first embodiment. As a result, the information retention time can be increased in the CMPK 114 according to the second embodiment without sacrificing the writing process performance at the normal time.

Next, the update process (S602 of FIG. 11) executed by the power supply monitoring unit 304 according to the second embodiment will be described with reference to FIG. 12. The power supply monitoring unit 304 according to the first embodiment issues the update command UA to the memory chip 144 in S703 and issues the write command WA to the memory chip 144 in S706. The power supply monitoring unit 304 according to the second embodiment issues the update command UAL to the memory chip 144 in S703 and issues the write command WAL to the memory chip 144 in S706 to increase the write time in the update process. The other points are the same as in the description of the first embodiment. The writing process with a long write operation time is executed, and the information retention time can be increased.

### Third Embodiment

Next, a third embodiment will be described. The hardware configuration of the storage system according to the third embodiment is the same as in the storage system according to the first or second embodiment.

The update command UA or UAL described in the first or second embodiment is a command for writing back the data stored in the memory area of the designated address to the memory area and sending back the data to the MEMCTL 143 of the command issuer. In the memory chip 144 according to the third embodiment, a command (will be called an update command UALI) for just writing back the data stored in the memory area of the designated address is newly defined.

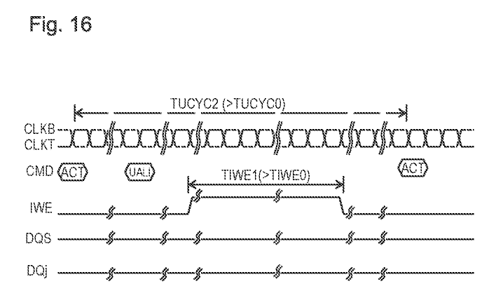

FIG. 16 shows a timing chart of the memory chip 144 when the update command UALI is received. The difference from the timing chart in FIG. 14 (update command UAL) is that the data strobe signal pin DQS and the data pin DQⱼ are maintained in a high impedance state, and the read operation to the outside of the chip is not performed.

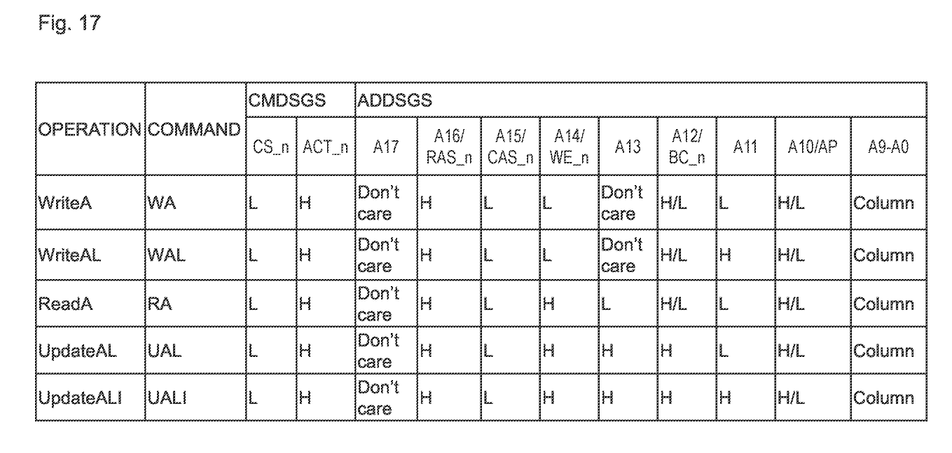

FIG. 17 shows an example of a truth table of each command supported by the memory chip 144 according to the third embodiment. As in the memory chip 144 according to the first or second embodiment, the commands are also defined in compliance with the DDR4 specification in the memory chip 144 according to the third embodiment. As in the memory chip 144 according to the first embodiment, A17, A13, and A11 undefined in the read command of the DRAM are used to define the commands.

Read command RA: (A17, A13, A11)=(Don't care, L, L)

Update command UAL: (A17, A13, A11)=(Don't care, H, L)

Update command UALI: (A17, A13, A11)=(Don't care, H, H)

p Next, functions of the CMPK 114 according to the third embodiment will be described. The CMPK 114 according to the third embodiment includes the same functional blocks as in the CMPK 114 described in the first or second embodiment. Therefore, the flow of the periodic update process described in the first embodiment is the same as in the CMPK 114 according to the third embodiment. The power failure monitoring process is almost the same as in the description of the first embodiment. However, the difference from the CMPK according to the first or second embodiment is that the CMPK 114 according to the third embodiment uses an update command UALI newly supported by the memory chip 144 in the update process (S602 of FIG. 11) executed by the power supply monitoring unit 304. There is no difference in other points.

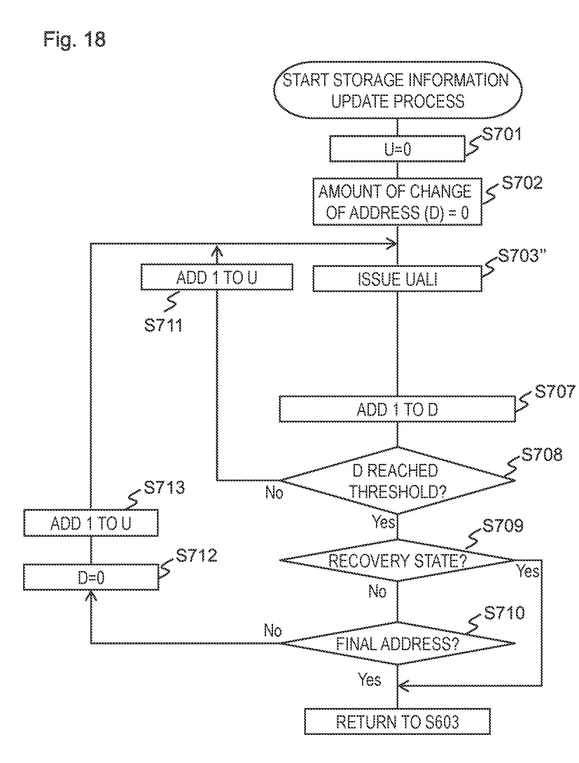

The update process (S602 of FIG. 11) executed by the power supply monitoring unit 304 according to the third embodiment will be described below with reference to FIGS. 18. S701 and S702 are the same as in the process described in FIG. 12.

In S703″, the power supply monitoring unit 304 issues the update command UALI to the memory chip 144. When the memory chip 144 receives the update command UALI, the memory chip 144 reads the data from the memory area of the designated address and writes the read data again to the memory area. The write time (current application time) in this case is the same as the write time in the update command UAL.

After S703″, the power supply monitoring unit 304 executes the process of S707 and subsequent steps. S707 to S713 are the same as in the description of the first embodiment.

In the update process of FIG. 18, the process of S704 to S706 in FIG. 12, that is, the ECC check and the data correction process of read data by the MEMCTL 143, is not executed. This is because the process of transmitting the data to the outside of the memory chip 144 is not executed when the memory chip 144 receives the update command UALI. Since the process of reading out the data to the outside of the memory chip 144 as well as the ECC check and the correction of the data are eliminated, the power required for the update process is reduced in the update process according to the third embodiment. Therefore, the capacity of the battery 13 can be reduced.

Although the embodiments of the present invention have been described, the embodiments are illustrated to describe the present invention, and this is not intended to limit the scope of the present invention to the embodiments. That is, the present invention can also be carried out in various other modes.

For example, although the MRAM or the STT-RAM is used as the memory chip 144 in the example described in the embodiments, other types of memory may be used. For example, a resistance change type memory, such as a ReRAM (Resistance Random Access Memory), a PCM (Phase Change Memory), and a PRAM (Phase-change Random Access Memory), may be used.

Although the memory chip 144 is mainly used as the cache memory of the storage system in the configurations described in the embodiments, the memory chip 144 may be used for other applications. For example, the memory chip 144 may be used as a main memory of the server.

Although the memory chip 144 that executes the long time update operation UpdateAL is described in the second embodiment, the memory chip 144 according to the second embodiment may support both the long time update operation UpdateAL and the update operation UpdateA described in the first embodiment. In the CMPK 114 according to the second embodiment, for example, the MEMCTL 143 may issue the update command UA in the periodic update process to cause the memory chip 144 to perform the update based on the update operation UpdateA, and the MEMCTL 143 may issue the update command UAL during the power failure to cause the memory chip 144 to perform the update based on the long time update operation UpdateAL. Furthermore, the memory chip 144 according to the third embodiment may also support the update command UA in addition to the update command UAL and the update command UALI.

### REFERENCE SIGNS LIST

2: host, 6: SAN, 7: management terminal, 10: storage system, 11: storage controller, 12: disk unit, 13: battery, 111: MPB, 112: FE I/F, 113: BE I/F, 114: CMPK, 115: switch, 141: MP, 142: local memory, 143: memory controller, 144: memory chip

1. A memory device comprising:
a memory chip using magnetoresistive elements as storage elements; and
a memory controller that controls the memory chip, wherein
when the memory controller receives a read request from an external device, the memory controller issues a read command to the memory chip to read data stored in the memory chip and sends back the data to the external device,
the memory controller further issues an update command to the memory chip independently from the read request from the external device, and
when the memory chip receives the update command, the memory chip writes back the data stored in the memory chip.

2. The memory device according to claim 1, wherein
when the memory controller receives a write request and data to be written from the external device,
the memory controller generates an error correcting code from the data to be written and stores the data to be written provided with the error correcting code in the memory chip.

3. The memory device according to claim 1, wherein
the memory controller executes a periodic update process of periodically issuing the update command to each area of the memory chip to cause each area of the memory chip to periodically write back the data.

4. The memory device according to claim 2, wherein
when the memory controller issues the update command to the memory chip,
the memory chip sends back the data stored in the area designated by the update command to the memory controller.

5. The memory device according to claim 4, wherein
the data sent back to the memory controller includes the error correcting code,
when the memory controller receives the data from the memory chip, the memory controller performs data check using the error correcting code, and
when a correctable error is detected as a result of the data check, the memory controller uses the error correcting code to correct the data and writes back the corrected data to the memory chip.

6. The memory device according to claim 5, wherein
the memory controller includes a skip address table that can store n (n≧1) addresses of areas designated by the write requests received from the external device in the past, and
the memory controller issues the update command to areas with addresses other than the addresses stored in the skip address table in the periodic update process.

7. The memory device according to claim 6, wherein
when the n addresses are already stored in the skip address table, the memory controller stores the address of the area designated by the write request received from the external device, in a field storing the address of an area for which the update command is issued last in the periodic update process.

8. The memory device according to claim 6, wherein
when the memory controller receives the write request from the external device, the memory controller stores, in the skip address table, the address of an area designated by the write request and date information of the time that the address is stored in the skip address table.

9. The memory device according to claim 8, wherein
when a difference between the date information stored in the skip address table and current date exceeds a predetermined threshold, the memory controller deletes the date information and the address corresponding to the date information from the skip address table.

10. The memory device according to claim 3, wherein
the memory device uses power supplied from an external power supply to operate at a normal time, and
when the supply of power from the external power supply is stopped, the memory controller uses power of a battery included in the memory device to issue the update command to all areas of the memory chip.

11. The memory device according to claim 10, wherein
when the memory chip receives a write command from the memory controller, the memory chip applies a current for a time TO to the storage element to be written designated by the write command to write data to the storage element, and
when the memory chip receives the update command from the memory controller, the memory chip reads data from the storage element to be updated designated by the update command and applies a current for a time T1 (T1≧T0) to the storage element to write back the data to the storage element.

12. A memory chip using magnetoresistive elements as storage elements, wherein
when the memory chip receives a read command from an external device, the memory chip reads data stored in the storage elements and sends back the data to the external device, and
when the memory chip receives a first update command from the external device, the memory chip reads the data stored in the storage elements and writes back the read data again to the storage elements.

13. The memory chip according to claim 12, wherein
when the memory chip receives the first update command from the memory controller, the memory chip applies a current for a time T0 to the storage element designated by the first update command to write back the data to the storage element, and
when the memory chip receives a second update command from the memory controller, the memory chip applies a current for a time T1 (T1≧T0) to the storage element designated by the second update command to write back the data to the storage element.

14. The memory chip according to claim 13, wherein
when the memory chip receives the second update command from the memory controller,
the memory chip sends back the data stored in the storage element to the external device and writes back the read data again to the storage element.
